(19) United States
(12) Patent Application Publication
(10) Pub. No.: US 2012/0291860 A1
(43) Pub. Date: Nov. 22, 2012

(54) SOLAR CELL AND METHOD OF MANUFACTURING THE SAME

(76) Inventors: Min PARK, Yongin-si (KR); Min-Seok OH, Yongin-si (KR); Yun-Seok LEE, Yongin-si (KR); Nam-Kyu SONG, Yongin-si (KR); Cho-Young LEE, Yongin-si (KR); Hoon-Ha JEON, Yongin-si (KR); Yeon-Ik JANG, Yongin-si (KR)

(21) Appl. No.: 13/472,744

(22) Filed: May 16, 2012

(30) Foreign Application Priority Data
May 19, 2011 (KR) 10-2011-0047415

(51) Int. Cl. H01L 31/0352; H01L 31/18; H01L 31/0224

(52) U.S. Cl. 136/255; 136/256; 438/72; 438/98; 257/E31.124; 257/E31.127

(57) ABSTRACT

A solar cell includes a base substrate having a first surface and a second surface opposite the first surface, the base substrate including a crystalline semiconductor and being configured to have solar light incident on the first surface, a doping pattern on a first portion of the second surface, the doping pattern including a first dopant, a first doping layer on a second portion of the second surface, the first doping layer including a second dopant, and the first and second portions of the second surface being different from each other, a first electrode on the first doping layer, and a second electrode on the doping pattern.

### BACKGROUND

1. Field

The described technology relates generally to a solar cell and to a manufacturing method thereof. More particularly, the described technology relates generally to a back surface electrode structure of a solar cell and a manufacturing method thereof.

2. Description of the Related Art

A solar cell is an energy conversion element changing solar light energy to electrical energy by applying a photovoltaic effect. When light enters a surface of a substrate of the solar cell, electrons and holes are generated in the solar cell and they move to first and second electrodes to generate photovoltaic power. Here, the photovoltaic power corresponds to a potential difference between the first and second electrodes. In this case, a current flows when a load is connected to the solar cell.

The above information disclosed in this Background section is only for enhancement of understanding of the background of the described technology and therefore it may contain information that does not form the prior art that is already known in this country to a person of ordinary skill in the art.

### SUMMARY

The described technology has been made in an effort to provide a highly effective solar cell that can be manufactured at low costs by simplifying a process.

The described technology has been also made in an effort to provide a highly effective solar cell that can be manufactured at a low temperature.

The described technology has been also made in an effort to provide a highly effective solar cell that includes a heterojunction and has a high open voltage.

The described technology also provides a manufacturing method of a solar cell with the features.

According to example embodiments, a solar cell may include a base substrate having a first surface and a second surface opposite the first surface, the base substrate including a crystalline semiconductor and being configured to have solar light incident on the first surface, a doping pattern on a first portion of the second surface, the doping pattern including a first dopant, a first doping layer on a second portion of the second surface, the first doping layer including a second dopant, and the first and second portions of the second surface being different from each other, a first electrode on the first doping layer, and a second electrode on the doping pattern.

The first doping layer may have a thickness of about 30 Å to about 500 Å.

The solar cell may further include a transparent conductive layer between the first doping layer and the first electrode and electrically connecting the first doping layer and the first electrode.

The transparent conductive layer may have a thickness of about 200 Å to about 1000 Å.

The solar cell may further include a first passivation layer between the first doping layer and the second portion of the second surface.

The first passivation layer may have a thickness of about 30 Å to about 200 Å.

Each of the first doping layer and the first passivation layer may include at least one of amorphous silicon (a-Si), amorphous silicon carbide (a-SiC), amorphous silicon oxide (a-SiOₓ), amorphous silicon nitride (a-SiNₓ), amorphous silicon oxynitride (a-SiOₓN_{y}), amorphous silicon carbonitride (a-SiCₓN_{y}), amorphous silicon oxicarbide (a-SiOₓC_{y}), and amorphous silicon oxicarbonitride (a-SiCₓO_{y}N_{z}).

The solar cell may further include a second doping layer on at least one surface of the base substrate other than the second surface.

Each of the doping pattern and the second doping layer may include a crystalline semiconductor.

The solar cell may further include an anti-reflection layer on the first surface.

The solar cell may further include a second passivation layer between the first surface of the base substrate and the anti-reflection layer.

Each of the anti-reflection layer and the second passivation layer may include at least one of amorphous silicon (a-Si), amorphous silicon carbide (a-SiC), amorphous silicon oxide (a-SiOₓ), amorphous silicon nitride (a-SiNₓ), amorphous silicon oxynitride (a-SiOₓN_{y}), amorphous silicon carbonitride (a-SiCₓN_{y}), amorphous silicon oxicarbide (a-SiOₓC_{y}), and amorphous silicon oxicarbonitride (a-SiCₓO_{y}N_{z}).

The second passivation layer may have a thickness of about 30 Å to about 200 Å.

The anti-reflection layer may have a thickness of about 800 Å to about 3000 Å.

The doping pattern and the first doping layer may be arranged in an alternating stripe pattern, an overall area of the doping pattern being larger than an overall area of the first doping layer.

According to other example embodiments, a manufacturing method of a solar cell may include preparing a base substrate with a first surface and a second surface opposite the first surface, the base substrate being formed of a crystalline semiconductor and being configured to have solar light incident on the first surface, forming a protection layer on a second portion of the second surface to expose a first portion of the second substrate, forming a doping pattern on the first portion of the second surface by diffusing a first dopant into the first portion, eliminating the protection layer, forming a first doping layer on the second portion of the second surface, the first doping layer including a second dopant, forming a first electrode on the first doping layer, and forming a second electrode on the doping pattern.

The manufacturing method may further include, before forming the first doping layer, forming a first passivation layer on the second portion of the second surface.

The manufacturing method may further include forming a second passivation layer on the first surface of the base substrate, the first and second passivation layers being simultaneously formed.

The manufacturing method may further include forming a second doping layer on at least one surface of the base substrate other than the second surface, and forming an anti-reflection layer on the second doping layer.

Forming the doping pattern may include supplying phosphorous oxychloride (POCl₃) and performing a diffusion process.

According to other example embodiments, a manufacturing method of a solar cell may include preparing a base substrate with a first surface and a second surface opposite the first surface, the base substrate being formed of a crystalline semiconductor and being configured to have solar light incident on the first surface, forming a passivation layer on the second surface, forming a doping layer on the passivation layer, the doping layer including a first dopant, forming a transparent conductive layer on the doping layer, exposing a first portion of the second surface by partially eliminating the passivation layer, the doping layer, and the transparent conductive layer, forming a doping pattern on the first portion of the second surface, the doping pattern including a second dopant, forming a first electrode on the doping layer, and forming a second electrode on the doping pattern.

The passivation layer and the doping layer may be formed of amorphous silicon.

Forming the passivation layer, forming the doping layer, forming the transparent conductive layer, partially eliminating the passivation layer, the doping layer, and the transparent conductive layer, forming the first electrode, and forming the second electrode may be performed at a temperature below 200° C.

### BRIEF DESCRIPTION OF THE DRAWINGS

Features will become apparent to those of ordinary skill in the art by describing in detail exemplary embodiments with reference to the attached drawings in which:

FIG. 1 illustrates a perspective view of a solar cell according to an exemplary embodiment.

FIG. 2 illustrates a cross-sectional view of FIG. 1 along line I-I′.

FIG. 3A to FIG. 3E illustrate cross-sectional views of stages in a manufacturing method of the solar cell of FIG. 2.

FIG. 4 illustrates a perspective view of a solar cell according to another exemplary embodiment.

FIG. 5 illustrates a cross-sectional view of FIG. 4 along line II-II′.

FIG. 6A to FIG. 6D illustrate cross-sectional views of stages in a manufacturing method of the solar cell of FIG. 5.

### DETAILED DESCRIPTION

Korean Patent Application No. 10-2011-0047415, filed on May 19, 2011, in the Korean Intellectual Property Office, and entitled: “Solar Cell and Method of Manufacturing the Same,” is incorporated by reference herein in its entirety.

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey the scope of the invention to those skilled in the art.

In the drawing figures, the dimensions of layers and regions may be exaggerated for clarity of illustration. It will also be understood that when a layer (or element) is referred to as being “on” another layer or substrate, it can be directly on the other layer or substrate, or intervening layers may also be present. In addition, it will also be understood that when a layer is referred to as being “between” two layers, it can be the only layer between the two layers, or one or more intervening layers may also be present. Like reference numerals refer to like elements throughout.

In the following detailed description, only certain exemplary embodiments have been shown and described, simply by way of illustration.

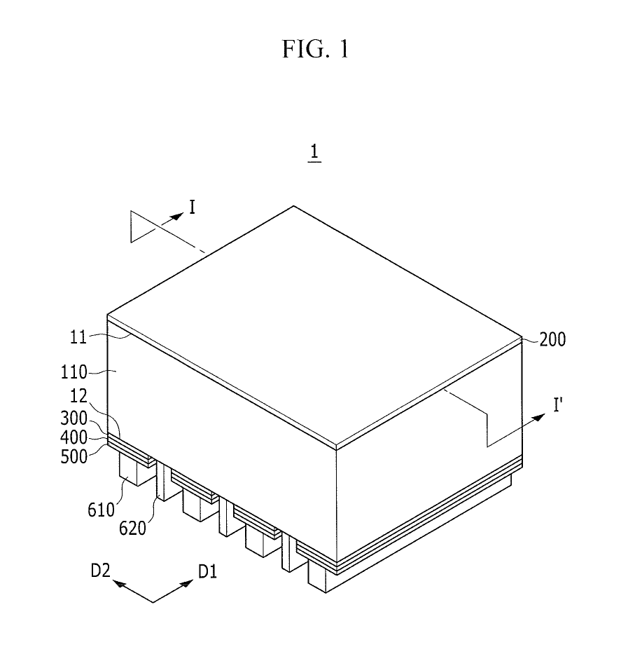

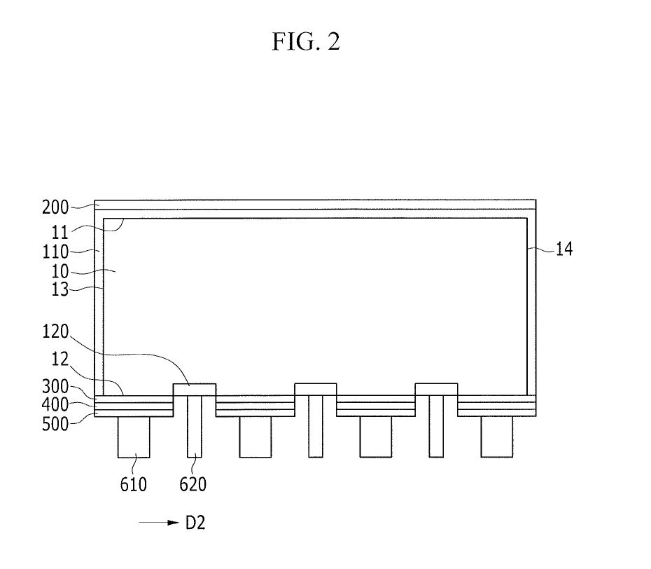

FIG. 1 is a perspective view of a solar cell according to an exemplary embodiment. FIG. 2 is a cross-sectional view of FIG. 1, taken along the line I-I′.

Referring to FIG. 1 and FIG. 2, a solar cell 1 according to the present exemplary embodiment may include an anti-reflection layer 200, a base substrate 10 where a second doping layer 110 and a doping pattern 120 are formed, a first passivation layer 300, a first doping layer 400, a transparent conductive layer 500, a first electrode 610, and a second electrode 620.

The base substrate 10 may include a first surface 11 on which solar light is incident, a second surface 12 facing the first surface 11, a third surface 13 connecting the first and second surfaces 11 and 12, and a fourth surface 14 facing the third surface 13. Although it is not shown, the first surface 11 may have concavo-convex patterns to minimize the reflectivity of solar light. The concavo-convex pattern increases light absorption area and diversifies directions of light passage. Thus, as the amount of incident light is increased and the area where the light reaches is increased, the number of electron hole pairs (EHP) is increased. The concavo-convex pattern, for example, may have a pyramidal shape. In this case, the pyramidal shape is not limited to the shape of a quadrangular pyramid, and it may be any shape having peaks and slopes. The pyramidal shape may have the shape of a hemisphere. The concavo-convex pattern may be formed on the first surface 11 and the second surface 12, e.g., through dipping texturing or in-line texturing where the base substrate 10 is immersed in an etching solution.

The base substrate 10 may be an n-type silicon substrate. That is, the base substrate 10 may include an element of group V. In the present exemplary embodiment, the base substrate 10 is described as the n-type silicon substrate, but it may be a p-type silicon substrate.

The second doping layer 110 may be formed on the first, third, and fourth surfaces 11, 13, and 14 of the base substrate 10. That is, the second doping layer 110 may be formed, e.g., continuously, on all the surfaces of the base substrate 10, excluding the second surface 12 that faces the first surface 11. The second doping layer 110 may include an n+ type semiconductor having a first dopant of high concentration. The first dopant may include an element of group V, e.g., phosphorus (P). Although it is not illustrated, the second doping layer 110 may be omitted.

In addition, a doping pattern 120, e.g., a plurality of doping patterns 120, may be formed on a part of the second surface 12 of the base substrate 10, e.g., the doping pattern may be selectively formed only on a portion of the second surface 12 of the base substrate 10. For example, the doping pattern 120 may extend in a first direction D1, and may be alternately formed in a second direction D2 that is substantially perpendicular to the first direction D1, e.g., the doping pattern 120 may be spaced apart from an adjacent doping pattern 120 in the second direction D2. For example, the doping pattern 120 may be formed in a checkerboard pattern, but is not limited thereto. The doping pattern 120 may include an n+ type semiconductor having the first dopant. The second doping layer 110 and the doping pattern 120 may be formed by diffusing dopants into a surface of the base substrate 10, e.g., by supplying phosphorus oxychloride (POCl₃) and performing a diffusion process.

The first passivation layer 300 may be formed on the second surface 12 of the base substrate 10 in an area not overlapping with the doping pattern 120. That is, the first passivation layer 300 and the doping pattern 120 may not overlap. The first passivation layer 300 may be formed of an amorphous intrinsic i-type semiconductor, and may overlap terminal edges of the second doping layer 110 on the third and fourth surfaces 13 and 14. Thus, movement of the holes and electrons between the second doping layer 110 on the third and fourth surfaces 13 and 14 and the first doping layer 400 may be prevented, thereby preventing recombination of the holes and the electrons. The first passivation layer 300 may include at least one of amorphous silicon (a-Si), amorphous silicon carbide (a-SiC), amorphous silicon oxide (a-SiOₓ), amorphous silicon nitride (a-SiNₓ), amorphous silicon oxynitride (a-SiOₓN_{y}), amorphous silicon carbonitride (a-SiCₓN_{y}), amorphous silicon oxicarbide (a-SiOₓC_{y}), and amorphous silicon oxicarbonitride (a-SiCₓO_{y}N_{z}). The first passivation layer 300 may have a thickness of about 30 Å to about 200 Å. The first passivation layer 300 may be formed using a chemical vapor deposition (CVD) or a low pressure chemical vapor deposition (LPCVD).

The first doping layer 400 may be formed on the first passivation layer 300, i.e., the first passivation layer 300 may be between the second surface 12 and the first doping layer 400. That is, the first doping layer 400 may not overlap the doping pattern 120, i.e., the first doping layer 400 and the doping pattern 120 may be formed on two different, i.e., mutually exclusive, portions of the second surface 12. The first doping layer 400 may be formed on a different layer than the doping pattern 120, i.e., relative to the second surface 12, so the first doping layer 400 may be vertically separated from the doping pattern 120. It is noted that the first passivation layer 300 facilitates prevention of overlap between the doping pattern 120 and the first doping layer 400, despite use of a diffusion process to form the doping pattern 120, so the first passivation layer 300 may prevent movement of holes and electrons between the doping pattern 120 and the first doping layer 400, which in turn, may prevent or substantially minimize hole-electron recombination.

The first doping layer 400 may include a second dopant. The first doping layer 400 may be formed of an amorphous p-type semiconductor. For example, the first doping layer 400 may include at least one of amorphous silicon (a-Si), amorphous silicon carbide (a-SiC), amorphous silicon oxide (a-SiOₓ), amorphous silicon nitride (a-SiNₓ), amorphous silicon oxynitride (a-SiOₓN_{y}), amorphous silicon carbonitride (a-SiCₓN_{y}), amorphous silicon oxicarbide (a-SiOₓC_{y}), and amorphous silicon oxicarbonitride (a-SiCₓO_{y}N_{z}). Further, the dopant may include an element of group III, e.g., boron (B), aluminum (Al), gallium (Ga), and/or indium (In). The first doping layer 400 may have a thickness of about 30 Å to about 500 Å. The first doping layer 400 may be formed using CVD.

As described above, the second doping layer 110 and the doping pattern 120 may be formed by diffusing the first dopant into the crystalline substrate, and the first doping layer 400 may be formed by depositing an amorphous semiconductor layer including the second dopant on the crystalline substrate. Therefore, the solar cell 1 may include a heterojunction of the crystalline silicon and the amorphous silicon.

In detail, the crystalline semiconductor may have an energy bandgap of about 1.1 eV, and the amorphous semiconductor may have an energy bandgap of about 1.7 eV to about 1.8 eV. Thus, as the solar cell 1 according to the present exemplary embodiment includes the heterojunction of the crystalline silicon and the amorphous silicon, the solar cell 1 may absorb light of a broad wavelength range due to the energy bandgap difference, thereby having a high open voltage Voc. Here, the open voltage Voc is an operation voltage that makes an output current zero, and the highest possible voltage of the solar cell in general. Since a maximum power of a solar cell improves as the open voltage increases, the solar cell 1 may be highly effective due to the resultant heterojunction structure and high open voltage Voc.

The transparent conductive layer 500 may be formed on the first doping layer 400, i.e., the first doping layer 400 may be between the second surface 12 and the transparent conductive layer 500. That is, the transparent conductive layer 500 may not overlap the doping pattern 120. The transparent conductive layer 500 may be formed of a single layer or a multi-layer including at least one of indium oxide (In₂O₃), zinc oxide (ZnO), or tin oxide (SnO₂). As the first doping layer 400 is formed of an amorphous semiconductor layer, i.e., metal ions may be diffused into the amorphous semiconductor layer of the first doping layer 400 upon contact with a metal layer, e.g., an electrode, the transparent conductive layer 500 may be formed to prevent diffusion of metal ions into the first doping layer 400. Further, the transparent conductive layer 500 may electrically connect the first electrode 610 with the first doping layer 400. The transparent conductive layer 500 may have a thickness of about 200 Å to about 1000 Å. The transparent conductive layer 500 may be formed using CVD, an evaporation method, a sputtering method, or a reactive plasma deposition (RPD).

The anti-reflection layer 200 may be formed on the second doping layer 110, i.e., the second doping layer 110 may be between the anti-reflection layer 200 and the first surface 11 of the base substrate 10. The anti-reflection layer 200 may minimize reflection of solar light incident on the first surface 11 of the base substrate 10. The anti-reflection layer 200 may be formed of the same material as the transparent conductive layer 500, or may be formed of a single layer or a multi-layer including at least one of amorphous silicon (a-Si), amorphous silicon carbide (a-SiC), amorphous silicon oxide (a-SiOₓ), amorphous silicon nitride (a-SiNₓ), amorphous silicon oxynitride (a-SiOₓN_{y}), amorphous silicon carbonitride (a-SiCₓN_{y}), amorphous silicon oxicarbide (a-SiOₓC_{y}), and amorphous silicon oxicarbonitride (a-SiCₓO_{y}N_{z}). The anti-reflection layer 200 may have a thickness of about 800 Å to about 3000 Å. The anti-reflection layer 200 may be formed using CVD, the evaporation method, the sputtering method, or RPD.

As described previously, the first passivation layer 300, the first doping layer 400, and the transparent conductive layer 500 may be formed not to overlap the doping pattern 120. Thus, if the first passivation layer 300, the first doping layer 400, or the transparent conductive layer 500 overlap the doping pattern 120 during their respective formation processes, an overlapping portion of the passivation layer, the second doping layer, or the transparent conductive layer may be eliminated using a laser or an etching paste method. Thus, as the doping pattern 120 and the first doping layer 400 do not overlap each other, electrons of the n-type semiconductor layer, i.e., electrons in the second doping layer 110 and doping pattern 120, and holes of the p-type semiconductor layer, i.e., holes in the first doping layer 400, may not be recombined.

The first electrode 610 may be formed on the transparent conductive layer 500, and the second electrode 620 may be formed on the doping pattern 120, e.g., the second surface 12 of the base substrate 10 may be between the doping pattern 120 and the second electrode 620. That is, the first electrode 610 may be electrically connected with the first doping layer 400 through the transparent conductive layer 500, and the second electrode 620 may be electrically connected with the doping pattern 120.

The first and second electrodes 610 and 620 may be formed according to the shapes of the doping pattern 120 and the first doping layer 400. Therefore, the first electrode 610 and the second electrode 620 may extend in the first direction D1 and may be alternately formed in the second direction D2, e.g., the first and second electrodes 610 and 620 may be alternately formed in a checkerboard pattern. The first and second electrodes 610 and 620 may include metal, e.g., at least one of aluminum (Al), silver (Ag), and copper (Cu), or an alloy thereof. The first and second electrodes 610 and 620 may have a single-layered structure formed of one material, or may have a multi-layered structure, e.g., Cu/TiW, Sn/Cu/TiW, Sn/Cu/Ni/Ag, Sn/Cu/Ni, or Sn/Cu. That is, when the first and second electrodes 610 and 620 are respectively formed in the multi-layered structure, one of a titanium-tungsten alloy (TiW), tin (Sn), nickel (Ni) may be included as a capping layer for preventing oxidation of each electrode or a seed layer for efficient plating of the electrode. The first and second electrodes 610 and 620 may be formed using, e.g., a screen printing method, an inkjet printing method, a gravure offset method, or a plating method.

Although not shown, a second passivation layer may be further formed on the anti-reflection layer 200 and the second surface 12 of the base substrate 10. The second passivation layer may prevent electron-hole recombination by preventing movement of the holes and the electrons between the second doping layer 110, the doping pattern 120, and the first doping layer 400. The second passivation layer may include at least one of amorphous silicon (a-Si), amorphous silicon carbide (a-SiC), amorphous silicon oxide (a-SiOₓ), amorphous silicon nitride (a-SiNₓ), amorphous silicon oxynitride (a-SiOₓN_{y}), amorphous silicon carbonitride (a-SiCₓN_{y}), amorphous silicon oxicarbide (a-SiOₓC_{y}), and amorphous silicon oxicarbonitride (a-SiCₓO_{y}N_{z}), and may be formed using a deposition method, e.g., CVD, LPCVD, etc.

In a conventional solar cell, electrodes may protrude from a first surface of a base substrate, i.e., from a surface on which solar light is incident, thereby causing shadowing that reduces the area on which the solar light is incident and deteriorating efficiency of the solar cell. However, in the solar cell 1 according to the present exemplary embodiment, both the first electrode 610 and the second electrode 620 are formed on the second surface 12 of the base substrate 10, so no electrodes are formed on the first surface 11, i.e., a surface on which solar light is incident, of the base substrate 10. Therefore, efficiency of the solar cell 1 may be improved.

In detail, in the solar cell 1 of the present exemplary embodiment, when solar light is incident on the first surface 11, holes and electrons are generated in the base substrate 10 by photons of the solar light. In this case, as the first and second electrodes 610 and 620 are formed on the second surface 12 facing the first surface 11, i.e., both the first and second electrodes 610 and 620 protrude from a same solar cell side that is opposite to a surface on which solar light is incident on, no shadowing occurs in the area on which the solar light is incident. As such, the area on which the solar light is incident may be maximized.

The holes move toward the doping pattern 120 by an electric field generated from the PN junction of the base substrate 10 and the first doping layer 400 formed of the amorphous silicon, and the electrons move toward the first doping layer 400 by the electric field. That is, since the first doping layer 400 is formed of amorphous semiconductor, it has a relatively large energy bandgap relative to the base substrate 10, e.g., when contacting the second doping layer 110, formed of the crystalline semiconductor. Therefore, electrons move toward the first doping layer 400, i.e., a p-type layer, and pass through the transparent conductive layer 500 to accumulate in the first electrode 610. The holes move toward the doping pattern 120, i.e., an n-type layer, to accumulate in the second electrode 620.

As the first doping pattern 120 and the first doping layer 400 are formed on the different layers and do not overlap with each other, they are separated from each other. As such, the electrons and the holes respectively accumulated on the first electrode 610 and the second electrode 620, thereby causing a potential difference. Accordingly, the solar cell 1 may generate electric power with solar light.

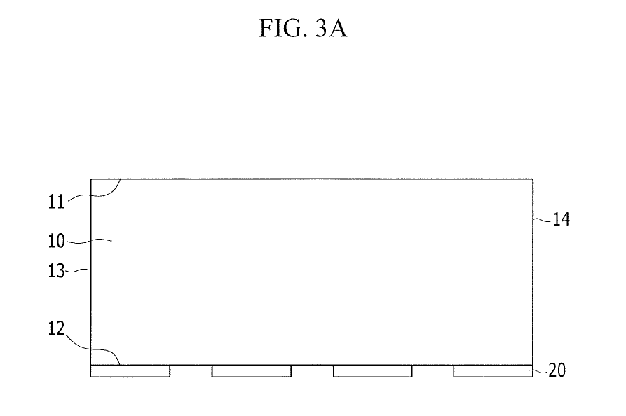

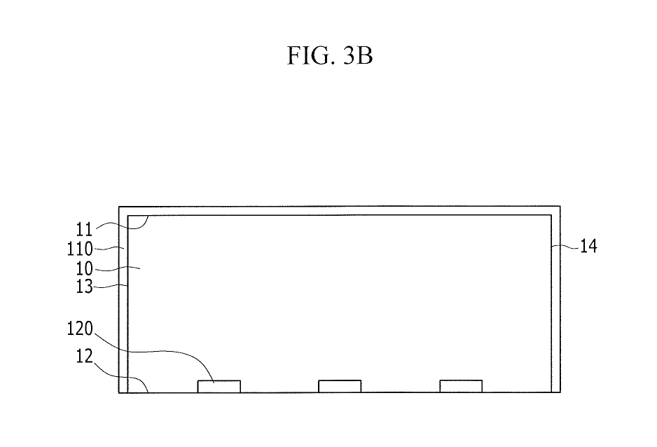

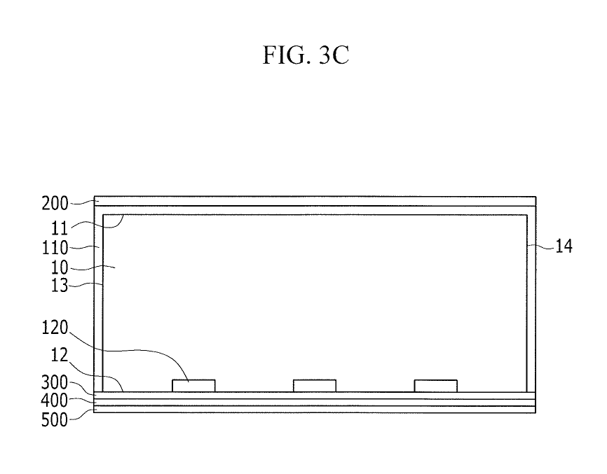

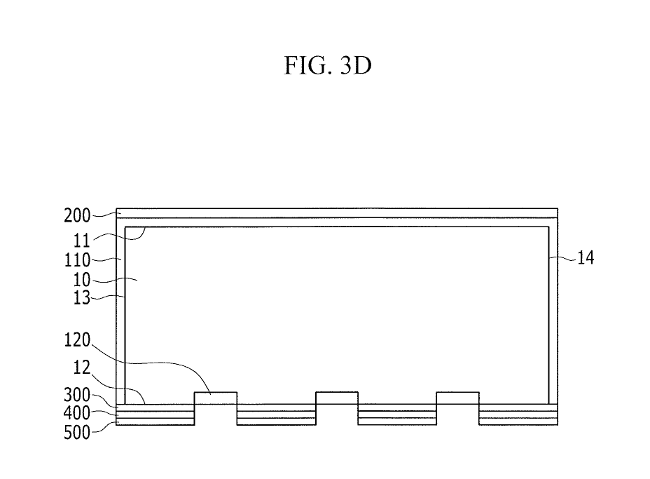

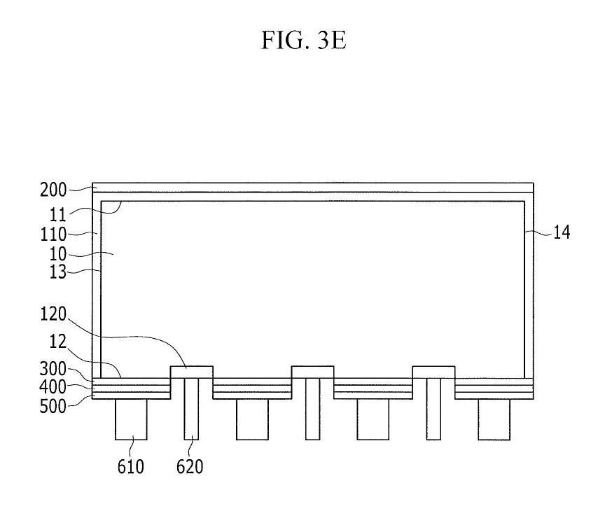

FIG. 3A to FIG. 3E are cross-sectional views of stages in a manufacturing method of the solar cell of FIG. 2.

Referring to FIG. 2 and FIG. 3A, the base substrate 10 may be prepared by partially etching, e.g., cutting, a surface of an n-type silicon substrate into a predetermined size. Damage to the base substrate 10 caused by the cutting process may be eliminated by wet-etching using an acid solution. The base substrate 10 may include the first surface 11 on which solar light is incident, the second surface 12 facing the first surface 11, the third surface 13 connecting the first surface 11 and the second surface 12, and the fourth surface 14 facing the third surface 13. Although it is not illustrated, the first and second surfaces 11 and 12 may include concavo-convex patterns, and may be formed using dipping texturing or in-line texturing. The concavo-convex pattern expands a light absorption area and varies a direction of a light movement passage. Thus, the number of electron-hole pairs increases as the amount of incident light is increased and the area where the light reaches is increased. The concavo-convex pattern may have, for example, a pyramid shape, but is not limited thereto.

The manufacturing method of the solar cell 1 according to the present exemplary embodiment uses the n-type silicon substrate for convenience, but a p-type silicon substrate may be used to form the base substrate 10.

A protection layer 20 may be partially formed on the second surface 12 of the base substrate 10. The protection layer 20 may be formed to prevent a doping layer from being formed in an area where the protection layer 20 is formed during a diffusion process. That is, the protection layer 20 may be formed to define an area to perform a diffusion process, i.e., an area to form the doping pattern 120, in the base substrate 10. Thus, the protection layer 20 is extended in the first direction D1 and alternately formed in the second direction D2. For example, the protection layer 20 may be formed in a checkerboard pattern, but it is not restrictive thereto. The protection layer 20 may be formed of one of a polymer resin, a photo-resistor, and a thin film that can be dissolved by hydrofluoric (HF) solution.

In general, it is easier to form an n-type semiconductor layer than to form a p-type semiconductor layer when the same concentration of a dopant is used. That is, since the n-type doping layer can be easily formed, it is not easy to form an n-type doping layer and a p-type doping layer respectively including the same concentration of a dopant. Thus, it is preferable that a physical area of the p-type semiconductor layer, i.e., the first doping layer 400 of the solar cell 1, is formed to be wide. Accordingly, as previously described, the first doping layer 400, i.e., the p-type semiconductor layer, may be formed in the area where the protection layer 20 is formed, and the doping pattern 120, i.e., the n-type semiconductor layer, may be formed in an area where the protection layer 20 is not formed. Therefore, the protection layer 20 may be formed to be larger than the portion where the protection layer 20 is not formed, i.e., a width between adjacent portions of the protection layer 20 may be smaller than a width of a single portion of the protection layer 20.

Referring to FIG. 2 and FIG. 3B, a part of the base substrate 10, i.e., the n-type semiconductor layer, may be formed as the second doping layer 110 and the doping pattern 120 through a diffusion process. Phosphorus oxychloride (POCl₃) may be supplied to the base substrate 10, to which the protection layer 20 is attached, followed by application of heat thereto. As a result, phosphorus (P) included in the phosphorus oxychloride becomes the first dopant, i.e., diffuses into the surface of the base substrate 10. Thus, parts of the first, third, and fourth surfaces 11, 13, and 14 of the base substrate 10 may be formed as the second doping layer 110. In addition, since the first dopant cannot be diffused into the area of the second surface 12 where the protection layer 20 is formed, a part of the second surface 12 where the protection layer 20 is not formed may be formed as the doping pattern 120. The phosphorus oxychloride (POCl₃) may be supplied in the state of liquid or gas. The diffusion process may be performed at a temperature of about 700° C. to about 1000° C.

Although it is not illustrated, when the diffusion process is performed, silicon (Si) and phosphorus oxychloride (POCl₃) of the base substrate 10 react with each other on the first, second, third, and fourth surfaces 11, 12, 13, and 14 of the base substrate 10, which the protection layer 20 is not formed thereon, so that a phosphorous silicate glass (PSG) layer may be formed. The PSG layer may be eliminated by performing a wet-etching method using hydrofluoric (HF) in order to avoid shielding a current flow in the solar cell 1.

When the base substrate 10 is formed of the p-type silicon substrate, boron tribromide (BBr₃) is supplied to the base substrate 10, instead of phosphorus oxychloride (POCl₃), and the diffusion process is performed such that the second doping layer 110, i.e., the p+ type semiconductor, is formed. Further, in this case, the boron-silicate glass (BSG) layer is formed on the second, third, and fourth surfaces 12, 13, and 14 of the base substrate 10, which the protection layer 20 is not formed thereon, and the BSG layer may be eliminated through the wet-etching method using hydrofluoric (HF) to avoid shielding the current flow in the solar cell 1.

When the phosphorus oxychloride (POCl₃) is supplied in the liquid state, the phosphorus oxychloride is diffused only into the second surface 12, i.e., where the protection layer 20 is formed, so that the second doping layer 110 may not be formed, i.e., on the first, third, and fourth surfaces. In addition, the protection layer 20 may be, continuously, formed on the first, third, and fourth surfaces 11, 13, and 14 to prevent diffusion of the first dopant into the first, third, and fourth surfaces 11, 13, and 14. Further, the second doping layer 110 formed on the second and third surfaces 12 and 13 may be eliminated using a laser and the like.

Referring to FIG. 2 and FIG. 3C, the first passivation layer 300 may be formed on the second surface 12 of the base substrate 10 and on the doping pattern 120 formed on the second surface 12. The first passivation layer 300 may be formed of an i-type semiconductor, and may include at least one of amorphous silicon (a-Si), amorphous silicon carbide (a-SiC), amorphous silicon oxide (a-SiOₓ), amorphous silicon nitride (a-SiNₓ), amorphous silicon oxynitride (a-SiOₓN_{y}), amorphous silicon carbonitride (a-SiCₓN_{y}), amorphous silicon oxicarbide (a-SiOₓC_{y}), and amorphous silicon oxicarbonitride (a-SiCₓO_{y}N_{z}). The first passivation layer 300 may have a thickness of about 30 Å to about 200 Å. The first passivation layer 300 may be formed using a deposition method, e.g., CVD. The CVD may be performed at a temperature below about 200° C.

Although it is not illustrated, a second passivation layer may be formed on the first surface 11 of the base substrate 10. The second passivation layer may include at least one of amorphous silicon (a-Si), amorphous silicon carbide (a-SiC), amorphous silicon oxide (a-SiOₓ), amorphous silicon nitride (a-SiNₓ), amorphous silicon oxynitride (a-SiOₓN_{y}), amorphous silicon carbonitride (a-SiCₓN_{y}), amorphous silicon oxicarbide (a-SiOₓC_{y}), and amorphous silicon oxicarbonitride (a-SiCₓO_{y}N_{z}). The second passivation layer may be continuously formed along with the first passivation layer 300 through a simultaneous process when using a LPCVD method.

The first doping layer 400 may be formed on the first passivation layer 300. The first doping layer 400 may include a second dopant. The first doping layer 400 may be formed of an amorphous p-type semiconductor layer. For example, the first doping layer 400 may include at least one of amorphous silicon (a-Si), amorphous silicon carbide (a-SiC), amorphous silicon oxide (a-SiOₓ), amorphous silicon nitride (a-SiNₓ), amorphous silicon oxynitride (a-SiOₓN_{y}), amorphous silicon carbonitride (a-SiCₓN_{y}), amorphous silicon oxicarbide (a-SiOₓC_{y}), and amorphous silicon oxicarbonitride (a-SiCₓO_{y}N_{z}). In addition, the second dopant may include an element of group III, e.g., one of boron (B), aluminum (Al), gallium (Ga), and indium (In). The first doping layer 400 may have a thickness of about 30 Å to about 500 Å. The first doping layer 400 may be formed using a CVD method. The CVD method may be performed at a low temperature below about 200° C. When the first passivation layer 300 and the first doping layer 400 are formed of the same material, they may be sequentially deposited through the same process.

The transparent conductive layer 500 may be formed on the first doping layer 400. The transparent conductive layer 500 may have a single-layered structure or a multi-layered structure including at least one of indium oxide (In₂O₃), zinc oxide (ZnO), and tin oxide (SnO₂). The transparent conductive layer 500 may have a thickness of about 200 Å to about 1000 Å. The transparent conductive layer 500 may be formed using a CVD method, an evaporation method, a sputtering method, or an RPD method.

The anti-reflection layer 200 may be formed on the second doping layer 110, i.e., on the first surface 11 of the base substrate 10. The anti-reflection layer 200 can minimize reflection of solar light incident on the first surface 11. The anti-reflection layer 200 may be formed of the same material as the transparent conductive layer 500, or may be formed of a single-layered structure of a multi-layered structure including at least one of amorphous silicon (a-Si), amorphous silicon carbide (a-SiC), amorphous silicon oxide (a-SiOₓ), amorphous silicon nitride (a-SiNₓ), amorphous silicon oxynitride (a-SiOₓN_{y}), amorphous silicon carbonitride (a-SiCₓN_{y}), amorphous silicon oxicarbide (a-SiOₓC_{y}), and amorphous silicon oxicarbonitride (a-SiCₓO_{y}N_{z}). The anti-reflection layer 200 may have a thickness of about 800 Å to about 3000 Å. The anti-reflection layer 200 may be formed using a CVD method, an evaporation method, a sputtering method, a sputtering method, or an RPD method.

Referring to FIG. 2 and FIG. 3D, portions of the first passivation layer 300, the first doping layer 400, and transparent conductive layer 500 overlapping with the doping pattern 120 are eliminated. In this case, the overlapped portions may be eliminated using a laser or an etching paste method.

In a conventional back electrode-type solar cell, an n-type semiconductor area and a p-type semiconductor area are formed on the same layer of the back surface of the solar cell, so that an additional isolation process preventing electron-hole recombination at the p-n junction area may be needed, or the n-type semiconductor area and the p-type semiconductor area may be formed to be separated from each other using a mask. However, according to the example embodiments, the doping pattern 120, i.e., the n-type semiconductor area, and the second doping layer 140, i.e., the p-type semiconductor area, are formed on different layers, i.e., may be separated from each other both vertically and horizontally not to overlap each other, so that neither an additional isolation process nor a complex process using a mask for separation are required. Accordingly, the process of the solar cell 1 may be simplified.

Referring to FIG. 2 and FIG. 3E, the first electrode 610 may be formed on the transparent conductive layer 500 overlapping with the first doping layer 400, and the second electrode 620 may be formed on the doping pattern 120. That is, the first electrode 610 is electrically connected with the first doping layer 400 through the transparent conductive layer 500, and the second electrode 620 is electrically connected to the doping pattern 120. Since the shapes of the first and second electrodes 610 and 620 depend on the shapes of the doping pattern 120 and the first doping layer 400, respectively, the first electrode 610 and the second electrode 620 may extend in the first direction D1 and alternately formed in the second direction D2. The first and second electrodes 610 and 620 may alternate with each other, forming a checkerboard pattern, but example embodiments are not limited thereto. The first and second electrodes 610 and 620 may respectively have a single-layered structure formed of the same material, or may have a multi-layered structure of Cu/TiW, Sn/Cu/TiW, Sn/Cu/Ni/Ag, Sn/Cu/Ni, and Sn/Cu. That is, when the first and second electrodes 610 and 620 respectively have the multi-layered structure, one of a titanium-tungsten alloy (TiW), tin (Sn), and nickel(Ni) may be included as a capping layer for prevention of oxidization of each electrode or a seed layer for effective plating of the electrode. The first and second electrodes 610 and 620 may be formed using a screen printing method, an ink-jet printing method, a gravure off-set method, or a plating method.

In general, an anti-reflection layer is formed on an upper portion of the solar cell, i.e., on a plane on which solar light is incident, so the electrodes are formed through the anti-reflection layer by a baking process at a temperature of about 700° C. or higher. However, the first and second electrodes 610 and 620 of the present exemplary embodiment are directly connected to the transparent conductive layer 500 and the doping pattern 120, so that the high-temperature backing process is unnecessary. Accordingly, the baking temperature may be formed at a low temperature, e.g., at about 200° C. or lower. Thus, other processes, excluding the diffusion process for forming the second doping layer 110 and the doping pattern 120, may be performed at a low temperature. Accordingly, a cross-dopant diffusion phenomenon in an emitter area, e.g., due to diffusion of phosphorus dopants into different semiconductor layers at a high temperature, may be prevented.

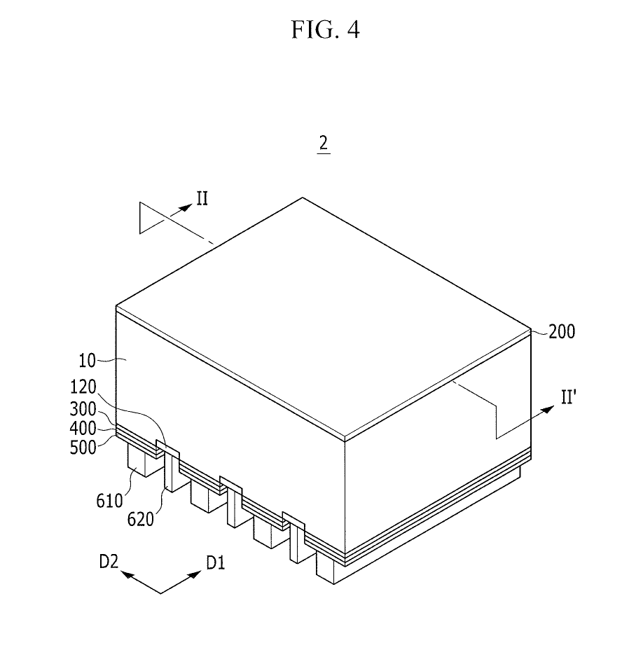

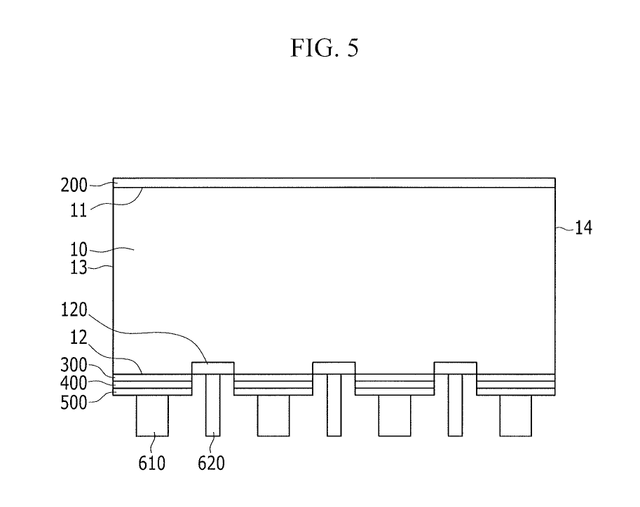

FIG. 4 is a perspective view of a solar cell according to another exemplary embodiment. FIG. 5 is a cross-sectional view of FIG. 4, taken along the line II-II'.

Referring to FIG. 4 and FIG. 5, a solar cell 2 according to the present exemplary embodiment is substantially the same as the solar cell 1 of FIG. 1 and FIG. 2, excluding that the second doping layer 110 formed on the first, third, and fourth surfaces 11, 13, and 14 of the base substrate 10 is omitted in the present exemplary embodiment. Therefore, a repeating description will be omitted.

The solar cell 2 according to the present exemplary embodiment includes the anti-reflection layer 200, the base substrate 10 where the doping pattern 120 is formed, the first passivation layer 300, the first doping layer 400, the transparent conductive layer 500, the first electrode 610, and the second electrode 620. When the second doping layer 110 is not formed on the third and fourth surfaces 13 and 14 of the base substrate 10, contact with the first doping layer 400, i.e., with the p-type semiconductor, may be further blocked. Accordingly, electron-hole recombination speed may be further slowed down.

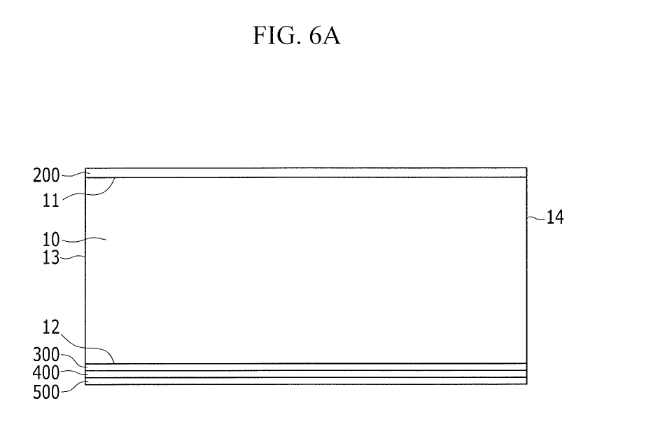

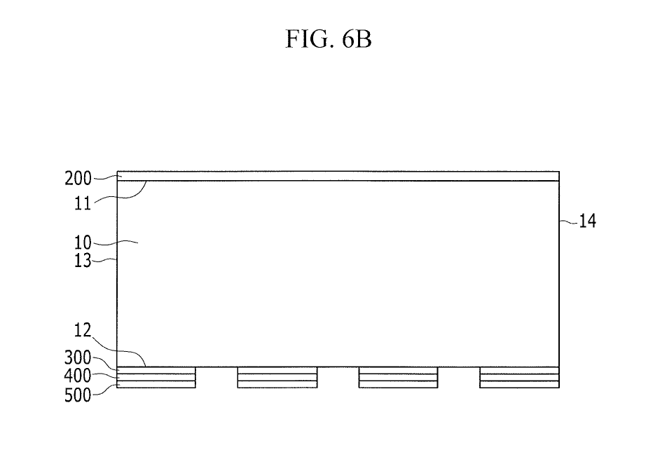

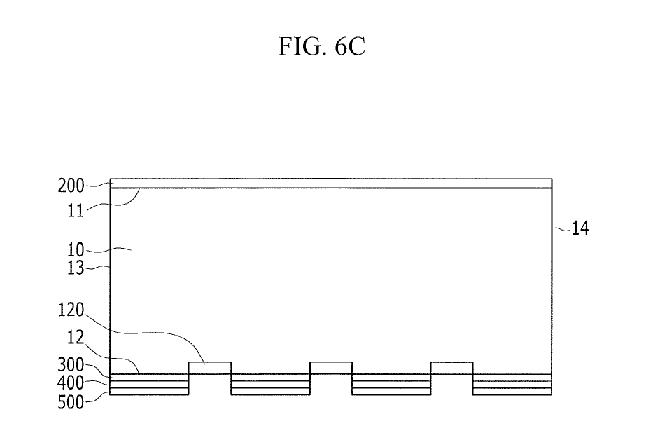

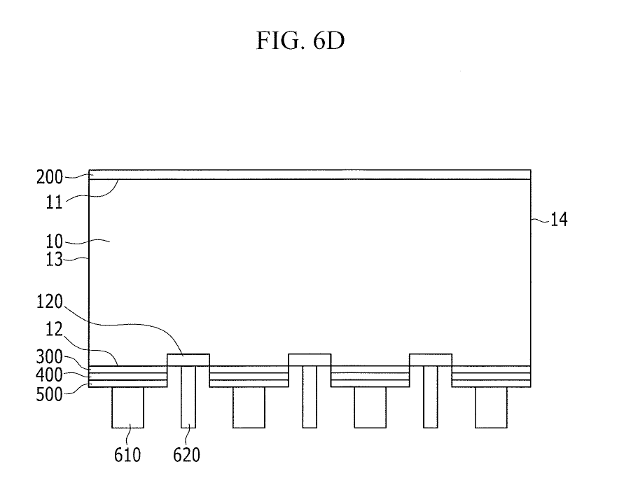

FIG. 6A to FIG. 6D are cross-sectional views of stages in a manufacturing method of the solar cell 2 of FIG. 5.

Referring to FIG. 5 and FIG. 6A, the base substrate 10 may be prepared by partially etching, e.g., cutting, an n-type silicon surface into a predetermined size. For convenience of description, the n-type silicon substrate is used to manufacture the solar cell 2 as in the previously described manufacturing method of the solar cell 2, but a p-type silicon substrate may be used as the base substrate 10.

The passivation layer 300 may be formed on the second surface 12 of the base substrate 10. The passivation layer 300 may be formed of an i-type semiconductor. For example, the passivation layer 300 may include one of amorphous silicon (a-Si), amorphous silicon carbide (a-SiC), amorphous silicon oxide (a-SiOₓ), amorphous silicon nitride (a-SiNₓ), amorphous silicon oxynitride (a-SiOₓN_{y}), amorphous silicon carbonitride (a-SiCₓN_{y}), amorphous silicon oxicarbide (a-SiOₓC_{y}), and amorphous silicon oxicarbonitride (a-SiCₓO_{y}N_{z}), and may have a thickness of about 30 Å to about 200 Å. The first passivation layer 300 may be formed using a deposition method such as CVD. The CVD may be performed through a low-temperature process at a temperature below about 200° C.

The first doping layer 400 may be formed on the first passivation layer 300. The first doping layer 400 may include a second dopant. The second dopant may include an element of group III, e.g., boron (B), aluminum (Al), gallium (Ga), indium (In). The first doping layer 400 may be formed of an amorphous p-type semiconductor. For example, the first doping layer 400 may include one of amorphous silicon (a-Si), amorphous silicon carbide (a-SiC), amorphous silicon oxide (a-SiOₓ), amorphous silicon nitride (a-SiNₓ), amorphous silicon oxynitride (a-SiOₓN_{y}), amorphous silicon carbonitride (a-SiCₓN_{y}), amorphous silicon oxicarbide (a-SiOₓC_{y}), and amorphous silicon oxicarbonitride (a-SiCₓO_{y}N_{z}). The first doping layer 400 may have a thickness of about 30 Å to about 500 Å. The first doping layer 400 may be formed using a CVD method. The CVD method may be performed at a low temperature below about 200° C. In addition, when the first passivation layer 300 and the first doping layer 400 are formed of the same material, the first passivation layer 300 and the first doping layer 400 may be continuously deposited through the same process.

The transparent conductive layer 500 may be formed on the first doping layer 400. The transparent conductive layer 500 may have a single-layered structure or a multi-layered structure including at least one of indium oxide (In₂O₃), zinc oxide (ZnO), tin oxide (SnO₂). The transparent conductive layer 500 may have a thickness of about 200 Å to about 1000 Å. The transparent conductive layer 500 may be formed using a CVD method, an evaporation method, a sputtering method, or an RPD method.

The anti-reflection layer 200 may be formed on the second surface 12 of the base substrate 10. The anti-reflection layer 200 may minimize reflection of solar light incident on the first surface 11. The anti-reflection layer 200 may have a thickness of about 800 Å to about 3000 Å, and may be formed using a CVD method, an evaporation method, a sputtering method, or an RPD method.

Referring to FIG. 5 and FIG. 6B, the first passivation layer 300, the first doping layer 400, and transparent conductive layer 500 may be partially eliminated, i.e., removed, to define area exposing portions of the second surface 12 of the base substrate 10. Thus, an area that is not eliminated becomes a p-type semiconductor area and the eliminated area, i.e., the exposed portions of the second surface 12, becomes an n-type semiconductor area through a process to be described later. The eliminated area is extended in the first direction D1 and alternately formed in the second direction D2. The eliminated area may be formed in the checkerboard pattern, but is not limited thereto. In addition, since the n-type doping is formed through a further simple process, it is not easy to form the n-type doping layer and the p-type doping layer respectively having the same concentration of dopant. Therefore, it is preferable to increase a physical area of the p-type semiconductor, i.e., the first doping layer 400, of the solar cell 2. Accordingly, the area that is not eliminated, i.e., the remaining portions of the layers 300 through 500, may be larger than the area to be eliminated, i.e., exposed portions of the second surface 12. Further, a laser or an etching paste method may be used for the elimination.

Referring to FIG. 5 and FIG. 6C, an n+ area, i.e., the doping pattern 120, may be formed by doping a high concentration of the first dopant into the exposed second surface 12. The doping pattern 120 may be formed using a doping paste method, a laser doping method, a chemical doping method, or an ion-implantation method. The doping pattern 120 may be formed by partially doping the exposed area of the base substrate 10, so no protection layer, e.g., a mask, may be needed. Further, since the second surface 12 of the base substrate 10 is partially doped, no doping layer is formed on the first, third, and fourth surfaces 11, 13, and 14. Accordingly, occurrence of electron-hole recombination caused by contact between the third and fourth surfaces 13 and 14 and the first doping layer 400 may be prevented.

Referring to FIG. 5 and FIG. 6D, the first electrode 610 may be formed on the first doping layer 400, and the second electrode 620 may be formed on the doping pattern 120. This is substantially the same as the manufacturing method of the solar cell 1 shown in FIG. 2.

As described above, a solar cell according to example embodiments may have a relatively high open voltage by including a heterojunction of the crystalline semiconductor and the amorphous semiconductor, while the n-type semiconductor layer and the p-type semiconductor layer are effectively separated. Further, the reflectivity of the solar cell may be reduced using the back electrode structure. As such, a highly efficient solar cell may be provided.

In addition, since an additional isolation process may be omitted in the manufacturing process of the solar cell, i.e., a process separating the p-type semiconductor layer from the n-type semiconductor layer, the whole manufacturing process may be simplified, thereby reducing manufacturing costs. Also, since most of the processes are performed at a low temperature, diffusion of dopants in the emitter area into other semiconductor layers may be prevented, thereby minimizing deformation of the doping layers caused by high temperature.

In contrast, a conventional solar cell may be formed of a crystalline semiconductor, i.e., without an amorphous layer, to include a homojunction. As such, the conventional solar cell may have a low open voltage and a complicated manufacturing process. Further, the method of manufacturing the conventional solar cell may include a process for forming a PN junction and an oxidation process at a high temperature, so that dopants in the n-type and p-type semiconductor layers in an emitter area may diffuse into other semiconductor layers due to the high temperature, thereby causing a cross dopant diffusion phenomenon.

<Description of symbols>

| | |
|---|---|
| 1, 2: solar cell | 10: base substrate |
| 400: first doping layer | 120: doping pattern |
| 200: anti-reflection layer | 300: first passivation layer |
| 110: second doping layer | 500: transparent conductive layer |
| 610: first electrode | 620: second electrode |

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A solar cell, comprising:
a base substrate having a first surface and a second surface opposite the first surface, the base substrate including a crystalline semiconductor and being configured to have solar light incident on the first surface;
a doping pattern on a first portion of the second surface, the doping pattern including a first dopant;
a first doping layer on a second portion of the second surface, the first doping layer including a second dopant, and the first and second portions of the second surface being different from each other;
a first electrode on the first doping layer; and
a second electrode on the doping pattern.

2. The solar cell as claimed in claim 1, wherein the first doping layer has a thickness of about 30 Å to about 500 Å.

3. The solar cell as claimed in claim 1, further comprising a transparent conductive layer between the first doping layer and the first electrode and electrically connecting the first doping layer and the first electrode.

4. The solar cell as claimed in claim 3, wherein the transparent conductive layer has a thickness of about 200 Å to about 1000 Å.

5. The solar cell as claimed in claim 1, further comprising a first passivation layer between the first doping layer and the second portion of the second surface.

6. The solar cell as claimed in claim 5, wherein the first passivation layer has a thickness of about 30 Å to about 200 Å.

7. The solar cell as claimed in claim 5, wherein each of the first doping layer and the first passivation layer includes at least one of amorphous silicon (a-Si), amorphous silicon carbide (a-SiC), amorphous silicon oxide (a-SiOₓ), amorphous silicon nitride (a-SiNₓ), amorphous silicon oxynitride (a-SiOₓN_{y}), amorphous silicon carbonitride (a-SiCₓN_{y}), amorphous silicon oxicarbide (a-SiOₓC_{y}), and amorphous silicon oxicarbonitride (a-SiCₓO_{y}N_{z}).

8. The solar cell as claimed in claim 1, further comprising a second doping layer on at least one surface of the base substrate other than the second surface.

9. The solar cell as claimed in claim 8, wherein each of the doping pattern and the second doping layer includes a crystalline semiconductor.

10. The solar cell as claimed in claim 1, further comprising an anti-reflection layer on the first surface.

11. The solar cell as claimed in claim 10, further comprising a second passivation layer between the first surface of the base substrate and the anti-reflection layer.

12. The solar cell as claimed in claim 11, wherein each of the anti-reflection layer and the second passivation layer includes at least one of amorphous silicon (a-Si), amorphous silicon carbide (a-SiC), amorphous silicon oxide (a-SiOₓ), amorphous silicon nitride (a-SiNₓ), amorphous silicon oxynitride (a-SiOₓN_{y}), amorphous silicon carbonitride (a-SiCₓN_{y}), amorphous silicon oxicarbide (a-SiOₓC_{y}), and amorphous silicon oxicarbonitride (a-SiCₓO_{y}N_{z}).

13. The solar cell as claimed in claim 11, wherein the second passivation layer has a thickness of about 30 Å to about 200 Å.

14. The solar cell as claimed in claim 10, wherein the anti-reflection layer has a thickness of about 800 Å to about 3000 Å.

15. The solar cell as claimed in claim 1, wherein the doping pattern and the first doping layer are arranged in an alternating stripe pattern, an overall area of the doping pattern being larger than an overall area of the first doping layer.

16. A manufacturing method of a solar cell, the method comprising:
preparing a base substrate with a first surface and a second surface opposite the first surface, the base substrate being formed of a crystalline semiconductor and being configured to have solar light incident on the first surface;
forming a protection layer on a second portion of the second surface to expose a first portion of the second substrate;
forming a doping pattern on the first portion of the second surface by diffusing a first dopant into the first portion;
eliminating the protection layer;
forming a first doping layer on the second portion of the second surface, the first doping layer including a second dopant;
forming a first electrode on the first doping layer; and
forming a second electrode on the doping pattern.

17. The manufacturing method of the solar cell as claimed in claim 16, further comprising, before forming the first doping layer, forming a first passivation layer on the second portion of the second surface.

18. The manufacturing method of the solar cell as claimed in claim 17, further comprising forming a second passivation layer on the first surface of the base substrate, the first and second passivation layers being simultaneously formed.

19. The manufacturing method of the solar cell as claimed in claim 16, further comprising:
forming a second doping layer on at least one surface of the base substrate other than the second surface and forming an anti-reflection layer on the second doping layer.

20. The manufacturing method of the solar cell as claimed in claim 16, wherein forming the doping pattern includes supplying phosphorous oxychloride (POCl₃) and performing a diffusion process.

21. A manufacturing method of a solar cell, the method comprising:
preparing a base substrate with a first surface and a second surface opposite the first surface, the base substrate being formed of a crystalline semiconductor and being configured to have solar light incident on the first surface;
forming a passivation layer on the second surface;
forming a doping layer on the passivation layer, the doping layer including a first dopant;
forming a transparent conductive layer on the doping layer;
exposing a first portion of the second surface by partially eliminating the passivation layer, the doping layer, and the transparent conductive layer;
forming a doping pattern on the first portion of the second surface, the doping pattern including a second dopant;
forming a first electrode on the doping layer; and
forming a second electrode on the doping pattern.

22. The manufacturing method of the solar cell as claimed in claim 21, wherein the passivation layer and the doping layer are formed of amorphous silicon.

23. The manufacturing method of the solar cell as claimed in claim 21, wherein forming the passivation layer, forming the doping layer, forming the transparent conductive layer, partially eliminating the passivation layer, the doping layer, and the transparent conductive layer, forming the first electrode, and forming the second electrode are performed at a temperature below 200° C.
